(19) United States
(12) Patent Application Publication
(10) Pub. No.: US 2025/0157875 A1
(43) Pub. Date: May 15, 2025

(54) SEMICONDUCTOR PACKAGE WITH HEAT DISSIPATION THROUGH THERMAL VIAS

(71) Applicant: SAMSUNG ELECTRONICS CO., LTD., Suwon-si (KR)

(72) Inventors: Jing Cheng LIN, Suwon-si (KR); Youngkun Jee, Suwon-si (KR)

(73) Assignee: SAMSUNG ELECTRONICS CO., LTD., Suwon-si (KR)

(21) Appl. No.: 18/939,702

(22) Filed: Nov. 7, 2024

(30) Foreign Application Priority Data
Nov. 9, 2023 (KR) 10-2023-0154570

(51) Int. Cl. H01L 23/367; H01L 23/00; H01L 23/31; H01L 23/48; H01L 23/498; H01L 25/16; H10B 80/00

(52) U.S. Cl. CPC H01L 23/3675; H01L 23/3128; H01L 23/3135; H01L 23/3677; H01L 23/481; H01L 23/49833; H01L 23/49838; H01L 24/16; H01L 25/16; H01L 2224/16145; H01L 2224/16225; H01L 2924/1815; H10B 80/00

(57) ABSTRACT

A semiconductor package includes: a first redistribution substrate; a first semiconductor chip on the first redistribution substrate, the first semiconductor chip comprising a semiconductor substrate and a plurality of first thermal vias penetrating through the semiconductor substrate in a first direction; a second semiconductor chip disposed on a center portion of the first semiconductor chip; and a plurality of second thermal vias arranged on a peripheral portion of the first semiconductor chip and arranged on an outer portion of the second semiconductor chip, wherein the plurality of second thermal vias are connected to the plurality of first thermal vias, respectively.

### CROSS-REFERENCE TO RELATED APPLICATION

This application is based on and claims priority under 35 U.S.C. § 119 to Korean Patent Application No. 10-2023-0154570, filed on Nov. 9, 2023, in the Korean Intellectual Property Office, the disclosures of which is incorporated by reference herein in its entirety.

### BACKGROUND

### 1. Field

The embodiments of the present disclosure relate to a semiconductor package, and more particularly, to a semiconductor package with improved heat dissipation characteristics.

### 2. Related Art

Due to the rapid developments of the electronics industry and demands of users, electronic devices are becoming smaller and lighter. As electronic devices are becoming smaller and lighter, semiconductor packages used therein are also becoming smaller and lighter, and such a semiconductor package is required to have high reliability, high performance, and large capacity. As such, a semiconductor package has higher performance and higher capacity requirements, thereby increasing power consumption. Therefore, the importance of heat dissipation characteristics of semiconductor packages is becoming more important.

### SUMMARY

The embodiments of the present disclosure provide a semiconductor package with improved heat dissipation characteristics.

In addition, the technical goals to be achieved by the embodiments of the present disclosure are not limited to the technical goals mentioned above, and other technical goals may be clearly understood by one of ordinary skill in the art from the following descriptions.

A semiconductor package comprises a first redistribution substrate; a first semiconductor chip on the first redistribution substrate, the first semiconductor chip comprising a semiconductor substrate and a plurality of first thermal vias penetrating through the semiconductor substrate in a first direction; a second semiconductor chip disposed on a center portion of the first semiconductor chip; and a plurality of second thermal vias arranged on a peripheral portion of the first semiconductor chip and arranged on an outer portion of the second semiconductor chip, wherein the plurality of second thermal vias are connected to the plurality of first thermal vias, respectively.

According to one or more embodiments, a semiconductor package comprises: a first redistribution substrate; a first semiconductor chip on the first redistribution substrate and comprising a semiconductor substrate and a plurality of first thermal vias penetrating through the semiconductor substrate in a first direction; a second semiconductor chip disposed on a center portion of the first semiconductor chip; a plurality of second thermal vias arranged on a peripheral portion of the first semiconductor chip and arranged on an outer portion of the second semiconductor chip; a plurality of conductive posts arranged on the first redistribution substrate and spaced apart from the first semiconductor chip in a second direction perpendicular to the first direction; a second redistribution substrate on the second semiconductor chip, the plurality of second thermal vias, and the plurality of conductive posts; a first molding member that contacts and surrounds the second semiconductor chip and the plurality of second thermal vias on the first semiconductor chip; and a second molding member that contacts and surrounds the first semiconductor chip, the first molding member, and the plurality of conductive posts, between the first redistribution substrate and the second redistribution substrate, wherein the plurality of second thermal vias are connected to the plurality of first thermal vias, respectively.

According to one or more embodiments, a semiconductor package comprising: a first redistribution substrate; a first semiconductor chip on the first redistribution substrate and comprising a semiconductor substrate and a plurality of first thermal vias penetrating through the semiconductor substrate in a first direction; a second semiconductor chip disposed on a center portion of the first semiconductor chip; a plurality of second thermal vias arranged on a peripheral portion of the first semiconductor chip and arranged on an outer portion of the second semiconductor chip; a plurality of conductive posts arranged on the first redistribution substrate and spaced apart from the first semiconductor chip in a second direction perpendicular to the first direction; a second redistribution substrate disposed on one or more of the plurality of second thermal vias and the plurality of conductive posts; a molding member that contacts and surrounds the first semiconductor chip, the second semiconductor chip, the plurality of second thermal vias, and the plurality of conductive posts on the first redistribution substrate; and a heat dissipation structure disposed on the second semiconductor chip to overlap at least a portion of the second semiconductor chip and the remaining second thermal vias of the plurality of second thermal vias in the first direction, wherein the plurality of second thermal vias are connected to the plurality of first thermal vias, respectively.

### BRIEF DESCRIPTION OF DRAWINGS

Embodiments of the present disclosure will be more clearly understood from the following detailed description taken in conjunction with the accompanying drawings in which:

FIG. 1 is a cross-sectional view of a semiconductor package according to one or more embodiments;

FIG. 2 is an enlarged view of a portion A of FIG. 1;

FIG. 3 is a cross-sectional view of a semiconductor package according to one or more embodiments;

FIG. 4 is a cross-sectional view of a semiconductor package according to one or more embodiments;

FIGS. 5A to 5H are diagrams schematically showing a process of manufacturing a stacked structure of the first semiconductor chip and the second semiconductor chip of FIG. 2;

FIGS. 6A to 6H are diagrams schematically showing a process of manufacturing the semiconductor package of FIG. 1; and

FIGS. 7A to 7C are diagrams schematically showing a process of manufacturing the semiconductor package of FIG. 3.

### DETAILED DESCRIPTION OF EMBODIMENTS

Hereinafter, embodiments of the present disclosure will be described in detail with reference to the attached drawings. The same reference numerals are used for the same components in the drawings, and duplicate descriptions thereof are omitted.

Hereinafter, example embodiments will be described with reference to the accompanying drawings. Hereinafter, terms, such as ‘top,’ ‘upper portion,’ ‘upper surface,’ ‘bottom,’ ‘lower portion,’ ‘lower surface,’ and ‘side surface’ may be understood as illustrated in the drawings, except for cases indicated by reference numerals.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

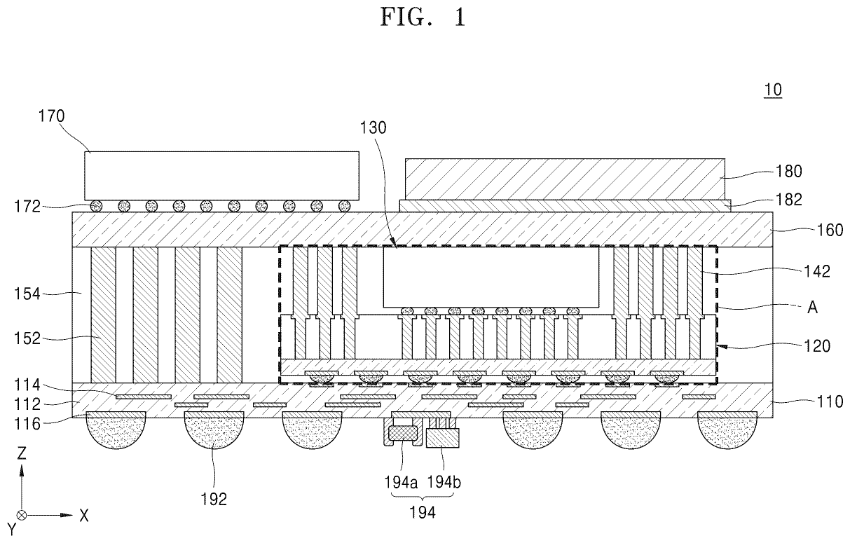

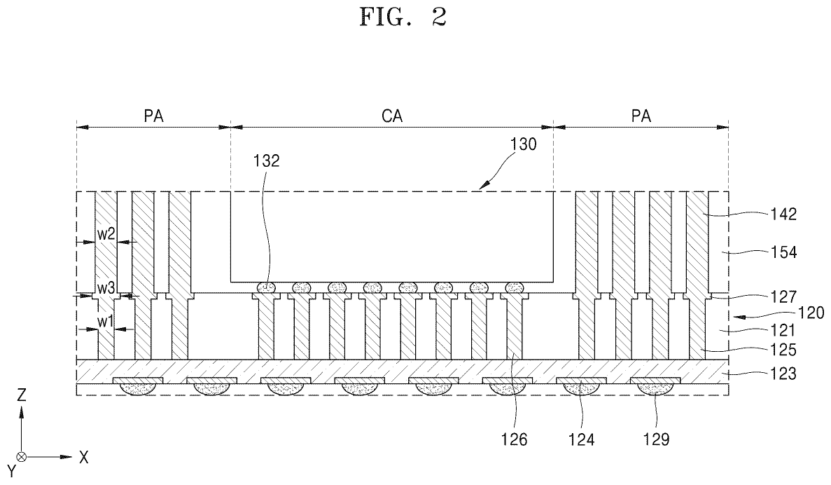

FIG. 1 is a cross-sectional view of a semiconductor package according to one or more embodiments. FIG. 2 is an enlarged view of a portion A of FIG. 1.

Referring to FIGS. 1 and 2, a semiconductor package 10 according to one or more embodiments may include a lower redistribution substrate 110, a first semiconductor chip 120, a second semiconductor chip 130, a second thermal via 142, a conductive post 152, a molding member 154, an upper redistribution substrate 160, a memory chip 170, and a heat dissipation structure 180.

The lower redistribution substrate 110 may be disposed below the first semiconductor chip 120, the conductive post 152, and the molding member 154. The lower redistribution substrate 110 may redistribute a first connection terminal 129 of the first semiconductor chip 120 to a region outside the first semiconductor chip 120. According to one or more embodiments, the lower redistribution substrate 110 may include a body insulation layer 112 and a redistribution line 114. As understood by one of ordinary skill in the art, a redistribution substrate or layer may be metal (e.g. copper) interconnects that electrically connect one part of a semiconductor package or chip to another. A redistribution layer may allow for creation of additional wiring on a chip, enabling the redistribution of I/O pads to different locations. These features provide enhanced chip-to-chip bonding by providing more flexible options for connecting integrated circuits (ICs) to other components.

In one or more examples, the body insulation layer 112 may include an insulation material (e.g., photo imageable dielectric (PID) resin or photo imageable polyimide (PIP) resin), and may further include an inorganic filler. However, materials constituting the body insulation layer 112 are not limited to the above-described materials, and may include any suitable material known to one of ordinary skill in the art.

In one or more examples, the body insulation layer 112 may have a multiple layer structure according to the multiple layer structure of redistribution lines 114. However, in FIG. 1, for convenience of explanation, the body insulation layer 112 is shown as a single layer structure. When the body insulation layer 112 has a multiple layer structure, multiple layers of the body insulation layer 112 may include the same material or different materials.

In one or more examples, the redistribution line 114 may include multiple layers, and the multiple layers of the redistribution line 114 may be connected to one another through a via. The redistribution line 114 and the via may include metals or alloys thereof. For example, the redistribution line 114 and the via may include copper (Cu).

According to one or more embodiments, the lower redistribution substrate 110 may further include a plurality of external connection pads 116 disposed at the bottom of the lower redistribution substrate 110. An external connection pad 116 may be formed to be electrically connected to the redistribution line 114. Alternatively, according to some embodiments, the lower redistribution substrate 110 may not include the plurality of external connection pads 116, and some of redistribution lines 114 may function as a plurality of external connection pads 116.

In one or more examples, a plurality of external connection terminals 192 may be arranged at the bottom of the lower redistribution substrate 110. According to one or more embodiments, the plurality of external connection terminals 192 may be arranged on the bottom surface of the body insulation layer 112. An external connection terminal 192 may be disposed on the external connection pad 116 formed at the bottom of the body insulation layer 112. For example, the external connection terminal 192 may be a bump or a solder ball.

In one or more examples, the external connection terminal 192 may be electrically connected to the redistribution line 114 through the external connection pad 116 of the lower redistribution substrate 110. Therefore, the external connection terminal 192 may be electrically connected to the first semiconductor chip 120 through the redistribution line 114 of the lower redistribution substrate 110 and the first connection terminal 129. In one or more examples, the external connection terminal 192 may connect the semiconductor package 10 to a package substrate of an external system or a main board of an electronic device such as a mobile device. The external connection terminal 192 may include a conductive material, for example, at least one of solder, tin (Sn), silver (Ag), copper (Cu), and aluminum (Al). However, the material constituting the external connection terminal 192 is not limited to the above-stated materials, any may include any other suitable materials known to one of ordinary skill in the art.

In one or more examples, the external connection terminals 192 may be arranged on a first bottom surface portion of the lower redistribution substrate 110 corresponding to the bottom surface of the first semiconductor chip 120 and a second bottom surface portion of the lower redistribution substrate 110 extending outward from the first bottom surface portion in a first horizontal direction (e.g., X direction). As such, a package structure in which the external connection terminals 192 are arranged in a region larger than the bottom surface of the first semiconductor chip 120 is referred to as a fan-out (FO) package structure. In one or more examples, a package structure in which the external connection terminals 192 are arranged only in a region corresponding to the bottom surface of the first semiconductor chip 120 is referred to as a fan-in (FI) package structure.

Passive devices 194 may be further arranged on the bottom surface of the lower redistribution substrate 110. According to embodiments, the passive devices 194 may be arranged on the top surface of or inside the lower redistribution substrate 110. The passive devices 194 may include two-terminal devices such as a resistor, an inductor, or a capacitor. In the semiconductor package 10 of the present embodiment, the passive devices 194 may include a multi-layer ceramic capacitor (MLCC) 194a and a Si-capacitor 194b.

In one or more examples, the first semiconductor chip 120 may be disposed on the lower redistribution substrate 110 and deviated to any one side in the first horizontal direction (e.g., X direction). For example, as shown in FIG. 1, the first semiconductor chip 120 may be disposed on the lower redistribution substrate 110 and deviated rightward in the first horizontal direction (e.g., X direction). Also, as the first semiconductor chip 120 is disposed to be deviated rightward in the first horizontal direction (e.g., X direction), the second semiconductor chip 130 and the heat dissipation structure 180 above the first semiconductor chip 120 may also be deviated rightward.

In one or more examples, the first semiconductor chip 120 may include a semiconductor substrate 121, a lower wiring layer 123, a first thermal via 125, a through via 126, and the first connection terminal 129.

An integrated circuit layer may be formed on the active surface of the semiconductor substrate 121. The integrated circuit layer may include a plurality of logic devices. The lower wiring layer 123 may be disposed at the bottom of the semiconductor substrate 121, (e.g., on the bottom surface of the semiconductor substrate 121), and may include multiple layers of wires. In the first semiconductor chip 120, the bottom surface may be the front surface, which may be an active surface, and the top surface may be the back surface, which may be an inactive surface. In one or more examples, the bottom surface of the semiconductor substrate 121, on which the lower wiring layer 123 is disposed, may correspond to the front surface of the first semiconductor chip 120, and the top surface of the semiconductor substrate 121 may correspond to the back surface of the first semiconductor chip 120.

In one or more examples, the lower wiring layer 123 may include a plurality of lower wiring lines, a plurality of lower wiring vias, a lower inter-wire insulation layer surrounding the plurality of lower wiring lines and the plurality of lower wiring vias. The plurality of lower wiring lines and the plurality of lower wiring vias may include a metal material such as copper (Cu), aluminum (Al), and tungsten (W). The lower inter-wire insulation layer may include a High Density Plasma (HDP) oxide layer, a TEOS oxide layer, a Tonen SilaZene (TOSZ) layer, a Spin-On-Glass (SOG) layer, an Undoped Silica Glass (USG) layer, or a low-k dielectric layer.

According to one or more embodiments, the lower wiring layer 123 may further include a plurality of lower connection pads 124 arranged at the bottom of the lower wiring layer 123. The lower connection pads 124 may be formed to be electrically connected to the lower wiring lines. According to some embodiments, the lower wiring layer 123 may not include the lower connection pads 124, and some of the lower wiring lines may function as the plurality of lower connection pads 124.

A plurality of first connection terminals 129 may be arranged at the bottom of the lower wiring layer 123. According to one or more embodiments, the plurality of first connection terminals 129 may be arranged on the plurality of lower connection pads 124 formed on the lower wiring layer 123. The first semiconductor chip 120 may be mounted on the lower redistribution substrate 110 through the first connection terminals 129. The first connection terminals 129 may be bumps or solder balls. According to some embodiments, the first connection terminals 129 may include metal pillars and solders. In one or more examples, the metal pillars may include Cu. However, the material constituting the metal pillars is not limited to Cu, and may include any other suitable material known known to one of ordinary skill in the art.

A plurality of first thermal vias 125 and a plurality of through vias 126 may be arranged to penetrate through the semiconductor substrate 121 in a vertical direction (e.g., Z direction).

In one or more examples, the plurality of through vias 126 may be arranged to penetrate through a horizontal (e.g., in X direction and/or Y direction) center portion CA of the semiconductor substrate 121 (e.g., hereinafter, referred to as the center portion of the first semiconductor chip 120). For example, the center portion CA of the first semiconductor chip 120 may be a region that overlaps the second semiconductor chip 130, as be described below. Furthermore, the center portion CA may be between the second thermal vias 142 A through via 126 may include, for example, copper (Cu). However, the material constituting the through via 126 is not limited to copper (Cu).

The lower portion of the through via 126 may be connected to the lower wiring layer 123, and the upper portion of the through via 126 may be connected to the second semiconductor chip 130. The bottom end of the through via 126 may be connected to a lower wiring via of the lower wiring layer 123, and thus the through via 126 may be electrically connected to the outside through the first connection terminal 129. An upper connection pad 127 may be disposed on the top of the through via 126, and thus the through via 126 may be electrically connected to the second semiconductor chip 130 through a second connection terminal 132.

The plurality of through vias 126 may form a path through which the first semiconductor chip 120 and the second semiconductor chip 130 transmit signals to each other. In one or more examples, the plurality of through vias 126 may provide power to the second semiconductor chip 130. For example, power may be provided to the second semiconductor chip 130 from the outside through a path formed along the first connection terminal 129, the lower wiring layer 123, and the plurality of through vias 126.

The plurality of first thermal vias 125 may be arranged to penetrate through a horizontal (in X direction and/or Y direction) peripheral portion PA of the semiconductor substrate 121 (hereinafter, referred to as the peripheral portion of the first semiconductor chip 120). For example, the peripheral portion PA of the first semiconductor chip 120 may be a region that does not overlap the second semiconductor chip 130, as be described below, and may refer to a region outside the center portion CA of the first semiconductor chip 120. Accordingly, as illustrated in FIG. 2, the peripheral portion surrounds the center portion CA in which the peripheral portion extends from an edge of the lower wiring layer 123 to the center portion CA. The first thermal via 125 may include, for example, copper (Cu). However, the material constituting the first thermal via 125 is not limited to copper (Cu).

In one or more examples, the lower portion of the first thermal via 125 may be connected to the lower wiring layer 123, and the upper portion of the first thermal via 125 may be connected to the second thermal via 142. The bottom ends of the first thermal vias 125 may be connected to the plurality of external connection terminals 192 through the lower wiring layer 123, the plurality of first connection terminals 129, and the lower redistribution substrate 110. Therefore, the first thermal vias 125 may dissipate heat generated by the first semiconductor chip 120 to the outside through the lower wiring layer 123, the plurality of first connection terminals 129, the lower redistribution substrate 110, and the plurality of external connection terminals 192. The upper connection pad 127 may be disposed on the top of the first thermal via 125, and thus heat generated in the first semiconductor chip 120 may be dissipated to the outside through the second thermal via 142.

The second semiconductor chip 130 may be disposed on the first semiconductor chip 120. According to embodiments, the second semiconductor chip 130 may be mounted on the first semiconductor chip 120 through second connection terminals 132. The second connection terminals 132 may be bumps or solder balls. According to some embodiments, the second connection terminals 132 may include metal pillars and solders. According to some embodiments, the second connection terminal 132 may be formed to be smaller than the first connection terminal 129.

In one or more examples, the second semiconductor chip 130 may be disposed on the first semiconductor chip 120 to overlap the center portion CA of the first semiconductor chip 120. The second connection terminal 132 of the second semiconductor chip 130 may be connected to the through via 126. In other words, the second semiconductor chip 130 may be disposed on the first semiconductor chip 120 such that the second connection terminals 132 may be electrically connected to the plurality of through vias 126. According to embodiments, the second connection terminal 132 may be connected to the through via 126 through the upper connection pad 127. As described above, the second semiconductor chip 130 may exchange signals with the first semiconductor chip 120 through the through via 126. In one or more examples, the second semiconductor chip 130 may receive power from the outside through a path formed along the plurality of through vias 126, the lower wiring layer 123, and the plurality of first connection terminals 129.

The first semiconductor chip 120 and the second semiconductor chip 130 may each be an analog chip. The first semiconductor chip 120 and the second semiconductor chip 130 may each include a plurality of logic devices therein. Here, a logic device is a device that performs various signal processing and may include, for example, an AND, OR, NOT, flip-flop, etc. Logic devices may also include devices to support communication. In the semiconductor package 10 of the present embodiment, the first semiconductor chip 120 and the second semiconductor chip 130 may each be, for example, an application processor (AP) chip. The first semiconductor chip 120 and the second semiconductor chip 130 may each be referred to as a control chip, a process chip, a CPU chip, etc., according to functions thereof. In one or more examples, in terms of integrated functionality, the first semiconductor chip 120 and the second semiconductor chip 130 may also be referred to as a system-on-chip (SoC). According to embodiments, devices to support communication may be separately provided as another chip, e.g., a modem chip, and may be disposed on the lower redistribution substrate 110 and coupled to the first semiconductor chip 120 and the second semiconductor chip 130.

In one or more examples, a plurality of second thermal vias 142 may be arranged on the first semiconductor chip 120. The plurality of second thermal vias 142 may be arranged on the first semiconductor chip 120 to overlap the peripheral portion PA of the first semiconductor chip 120. For example, the plurality of second thermal vias 142 may be arranged on the first semiconductor chip 120 and outside the second semiconductor chip 130. The second thermal via 142 may include the same material as the first thermal via 125, e.g., copper (Cu). However, the material constituting the second thermal via 142 does not need to be identical to the material constituting the first thermal via 125, and may include any other suitable material known to one of ordinary skill in the art.

The plurality of second thermal vias 142 may be connected to the plurality of first thermal vias 125, respectively. For example, the second thermal via 142 may be disposed on the first semiconductor chip 120 to contact the top end of the first thermal via 125. According to embodiments, the second thermal via 142 may directly contact the upper connection pad 127 and be connected to the first thermal via 125 through the upper connection pad 127. As described above, the second thermal via 142 may be connected to the first thermal via 125 and dissipate heat generated by the first semiconductor chip 120 to the outside.

A horizontal width w2 (e.g., X direction) of the second thermal via 142 may have a greater value than a horizontal width w1 of the first thermal via 125. According to some embodiments, when the upper connection pad 127 is disposed on top of the first thermal via 125, a horizontal width w3 of the upper connection pad 127 may have a greater value than the horizontal width w2 of the second thermal via 142. However, the relative difference between widths of the first thermal via 125 and the second thermal via 142 is not limited thereto, and the horizontal width w1 of the first thermal via 125 and the horizontal width w2 of the second thermal via 142 may be identical to each other according to necessary heat dissipation performance.

In one or more examples, the second thermal via 142 may have a structure extending through the molding member 154 in the vertical direction (e.g., Z direction). The arrangement between the second thermal via 142 and the molding member 154 is described below.

The conductive post 152 may be disposed on the lower redistribution substrate 110. The conductive post 152 may be disposed on the lower redistribution substrate 110 and spaced apart from the first semiconductor chip 120 in the first horizontal direction (e.g., X direction). According to embodiments, a plurality of conductive posts 152 may be arranged such that the conductive posts 152 are spaced apart from each other.

The conductive post 152 may be disposed to extend in the vertical direction (e.g., Z direction) between the lower redistribution substrate 110 and the upper redistribution substrate 160. In addition, the molding member 154 may be disposed between the lower redistribution substrate 110 and the upper redistribution substrate 160. Therefore, the conductive post 152 may have a structure extending through the molding member 154 in the vertical direction (e.g., Z direction).

The conductive post 152 may electrically connect the memory chip 170 to the lower redistribution substrate 110. For example, the bottom surface of the conductive post 152 may be connected to the redistribution line 114 of the lower redistribution substrate 110, and the top surface of the conductive post 152 may be connected to the memory chip 170 through the upper redistribution substrate 160.

The conductive post 152 may include, for example, copper (Cu). Therefore, the conductive post 152 may be referred to as a Cu post. However, the material constituting the conductive post 152 is not limited to copper (Cu), and may include any suitable material known to one of ordinary skill in the art. The conductive post 152 may be formed through electroplating using a seed metal. The seed metal may include various metal materials, such as copper (Cu), titanium (Ti), tantalum (Ta), titanium nitride (TiN), and tantalum nitride (TaN). In the semiconductor package 10, according to one or more embodiments, the seed metal may be included as a part of the conductive post 152. For example, the seed metal may include copper (Cu), and the conductive post 152 may also include copper (Cu). Therefore, the seed metal is not separately shown in FIG. 1.

The molding member 154 may be disposed between the lower redistribution substrate 110 and the upper redistribution substrate 160 to contact and surround the first semiconductor chip 120, the second semiconductor chip 130, the plurality of second thermal vias 142, and the plurality of conductive posts 152.

The molding member 154 may surround the side surfaces and the top surface of the first semiconductor chip 120 and the side surfaces of the second semiconductor chip 130. The molding member 154 may fill the space between the first connection terminal 129 on the bottom surface of the first semiconductor chip 120 and the second connection terminal 132 on the bottom surface of the second semiconductor chip 130. However, according to some embodiments, the space between the first connection terminal 129 on the bottom surface of the first semiconductor chip 120 and the second connection terminal 132 on the bottom surface of the second semiconductor chip 130 may be filled with an underfill, and the molding member 154 may cover the side surfaces of the first semiconductor chip 120, the second semiconductor chip 130, and the underfill.

In one or more examples, the molding member 154 may be disposed to surround the side surfaces of the plurality of second thermal vias 142 and the plurality of conductive posts 152. The side surface of the second thermal via 142 is surrounded by the molding member 154, but the top surface of the second thermal via 142 may be exposed on the top of the molding member 154 and connected to the upper redistribution substrate 160. In one or more examples, the side surface of the conductive post 152 is surrounded by the molding member 154, but the top surface of the conductive post 152 may be exposed on the top of the molding member 154 and connected to the upper redistribution substrate 160. For example, the top surface of the second thermal via 142, the top surface of the conductive post 152, and the top surface of the molding member 154 may be coplanar with one another.

The molding member 154 may include thermosetting resin such as epoxy resin, thermoplastic resin such as polyimide, or thermosetting resin or thermoplastic resin containing reinforcing materials such as an inorganic filler (e.g., Ajinomoto Build-up Film (ABF), FR-4, BT, etc.), but the embodiments are not limited thereto. For example, the molding member 154 may include a molding material such as Epoxy Mold Compound (EMC) or a photosensitive material such as Photo Imageable Encapsulant (PIE). According to some embodiments, a portion of the molding member 154 may include an insulation material such as a silicon oxide film, a silicon nitride film, or a silicon oxynitride film.

The upper redistribution substrate 160 may be disposed on the second semiconductor chip 130, the plurality of second thermal vias 142, and the plurality of conductive posts 152. The upper redistribution substrate 160 may redistribute the memory chip 170 disposed thereabove. The upper redistribution substrate 160 may be formed in a structure similar to that of the lower redistribution substrate 110. For example, the upper redistribution substrate 160 may include a body insulation layer including an insulation material and a redistribution line including a metal such as copper (Cu).

The upper portion of the upper redistribution substrate 160 may be electrically connected to the memory chip 170, and the lower portion of the upper redistribution substrate 160 may be electrically connected to the plurality of conductive posts 152. According to embodiments, the lower portion of the upper redistribution substrate 160 may be electrically connected to the plurality of second thermal vias 142. In one or more examples, according to embodiments, the lower portion of the upper redistribution substrate 160 may be electrically connected to the second semiconductor chip 130.

The memory chip 170 and the heat dissipation structure 180 may be arranged on the upper redistribution substrate 160.

The memory chip 170 may be placed on the upper redistribution substrate 160 and spaced apart from the heat dissipation structure 180. The memory chip 170 may be disposed on the upper redistribution substrate 160 and deviated leftward in the first horizontal direction (e.g., X direction). Therefore, the memory chip 170 may be arranged to overlap the plurality of conductive posts 152, a portion of the first semiconductor chip 120, and a portion of the second thermal via 142 in the vertical direction (e.g., Z direction). The memory chip 170 may be a single chip or a package including a plurality of chips. When the memory chip 170 is a package, the semiconductor package 10 of the present embodiment may correspond to a Package-On-Package (POP) structure.

In one or more examples, the memory chip 170 may include a plurality of memory devices therein. The memory chip 170 may include, for example, a volatile memory device, such as dynamic random access memory (DRAM) and static random access memory (SRAM), or a non-volatile memory device, such as flash memory. For example, the memory chip 170 may be a High Bandwidth Memory (HBM) package including a base chip and a plurality of core chips. The memory chip 170 may be mounted on the upper redistribution substrate 160 through bumps 172 in a flip-chip manner.

In one or more examples, the memory chip 170 may be electrically connected to the upper redistribution substrate 160. The memory chip 170 may receive a power signal from the outside through the upper redistribution substrate 160, the conductive post 152, the lower redistribution substrate 110, and the external connection terminal 192. The memory chip 170 may be electrically connected to the second semiconductor chip 130 through the upper redistribution substrate 160. Therefore, the memory chip 170 may exchange memory signals with the second semiconductor chip 130 through the upper redistribution substrate 160. In one or more examples, according to embodiment, the memory chip 170 may receive a part of power through a path formed along the plurality of first connection terminals 129, the lower wiring layer 123, the plurality of first thermal vias 125, the plurality of second thermal vias 142, and the upper redistribution substrate 160.

In one or more examples, the heat dissipation structure 180 may be disposed on the upper redistribution substrate 160 and spaced apart from the memory chip 170. The heat dissipation structure 180 may be disposed on the upper redistribution substrate 160 and deviated rightward in the first horizontal direction (e.g., X direction). Therefore, the heat dissipation structure 180 may be disposed to overlap at least a portion of the second semiconductor chip 130 in the vertical direction (e.g., Z direction). In one or more examples, the heat dissipation structure 180 may be disposed to overlap at least some of the plurality of second thermal vias 142 in the vertical direction (e.g., Z direction). The heat dissipation structure 180 may be disposed to overlap the second semiconductor chip 130 and the plurality of second thermal vias 142 in the vertical direction (e.g., Z direction) and perform a heat dissipation function with respect to the first semiconductor chip 120 and the second semiconductor chip 130.

The heat dissipation structure 180 may be stacked on the upper redistribution substrate 160 through an adhesive layer 182. The heat dissipation structure 180 may include, for example, a heat sink or a heat slug. The adhesive layer 182 may include a material with high thermal conductivity. The adhesive layer 182 may adhere and fix the heat dissipation structure 180 onto the upper redistribution substrate 160. The adhesive layer 182 may slightly protrude from the side surfaces of the heat dissipation structure 180, as shown in FIG. 1. For example, the adhesive layer 182 may include a Thermal Interface Material (TIM) or thermally conductive resin. The TIM may include materials with high thermal conductivity, that is, low thermal resistance, such as grease, tape, an elastomer filling pad, and a phase-change material.

The heat dissipation effect of the first semiconductor chip 120 and the second semiconductor chip 130 may be advantageously maximized through the arrangement of the heat dissipation structure 180, the first thermal via 125, and the second thermal via 142. In a conventional semiconductor package in which a first semiconductor chip and a second semiconductor chip are stacked vertically, heat dissipation of the first semiconductor chip disposed at the bottom may not be smooth. However, in the semiconductor package 10 of the present embodiment, the first thermal via 125 vertically penetrating through the semiconductor substrate 121 of the first semiconductor chip 120 is directly connected to the second thermal via 142, and the second thermal via 142 may be connected to the heat dissipation structure 180 with the upper redistribution substrate 160 therebetween. Therefore, heat generated by the first semiconductor chip 120 may be transferred to the heat dissipation structure 180 through the first thermal via 125 and the second thermal via 142, and thus, the heat dissipation effect of the first semiconductor chip 120 is significantly improved. In one or more examples, the hot spot region of the second semiconductor chip 130 overlaps the heat dissipation structure 180 in the vertical direction (Z direction), and thus heat generated by the second semiconductor chip 130 may be transferred to the heat dissipation structure 180.

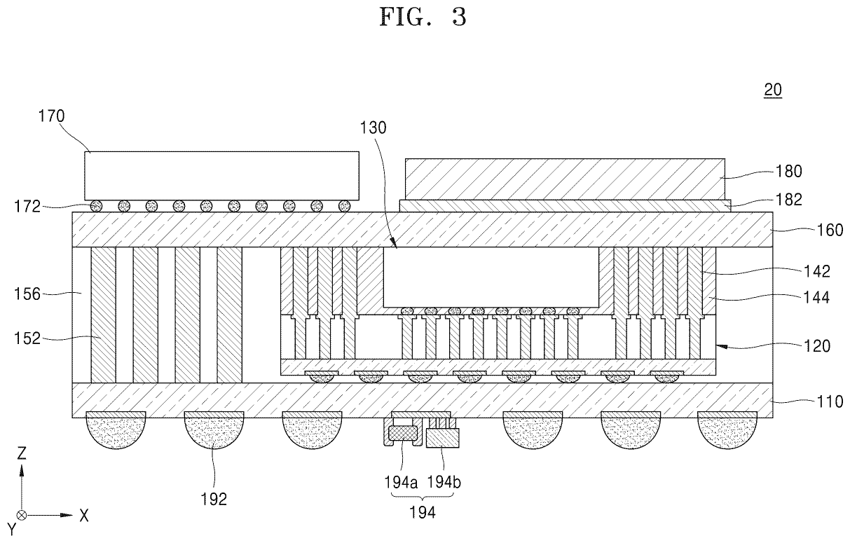

FIG. 3 is a cross-sectional view of a semiconductor package according to one or more embodiments. Hereinafter, descriptions of the semiconductor package 10 of FIGS. 1 to 2 and a semiconductor package 20 of FIG. 3 identical to each other are omitted, and the focus is on the differences therebetween.

Referring to FIG. 3, the semiconductor package 20 may be different from the semiconductor package 10 of FIG. 1 in that a first molding member 144 and a second molding member 156 are distinguished from each other.

In detail, in the semiconductor package 20 according to one or more embodiments, the first molding member 144 may be disposed to contact and surround the second semiconductor chip 130 and the plurality of second thermal vias 142 on the first semiconductor chip 120. The first molding member 144 may fill the space between the side surfaces of the second semiconductor chip 130 and the second connection terminal 132 on the bottom surface of the second semiconductor chip 130. However, according to some embodiments, the space between the second connection terminals 132 on the bottom surface of the second semiconductor chip 130 may be filled with an underfill, and the first molding member 144 may cover the side surfaces of the second semiconductor chip 130 and the underfill. The side surface of the second thermal via 142 is surrounded by the first molding member 144, but the top surface of the second thermal via 142 may be exposed on the top of the first molding member 144 and connected to the upper redistribution substrate 160.

The second molding member 156 may correspond to a portion of the molding member 154 of FIG. 1 excluding a portion of the molding member 154 corresponding to the first molding member 144. The second molding member 156 may be disposed between the lower redistribution substrate 110 and the upper redistribution substrate 160 to contact and surround the first semiconductor chip 120, the first molding member 144, the plurality of conductive posts 152. The second molding member 156 may fill the space between the side surfaces of the first semiconductor chip 120 and the first connection terminal 129 on the bottom surface of the first semiconductor chip 120. However, according to some embodiments, the spaces between the first connection terminals 129 on the bottom surface of the first semiconductor chip 120 may be filled with an underfill, and the second molding member 156 may cover the sidewalls of the first semiconductor chip 120 and the underfill. The side surface of the conductive post 152 is surrounded by the second molding member 156, but the top surface of the conductive post 152 may be exposed on the top of the second molding member 156 and connected to the upper redistribution substrate 160.

The first molding member 144 and the second molding member 156 may include the same material as the molding member 154 described with reference to FIGS. 1 and 2. According to embodiments, the first molding member 144 and the second molding member 156 may include different materials.

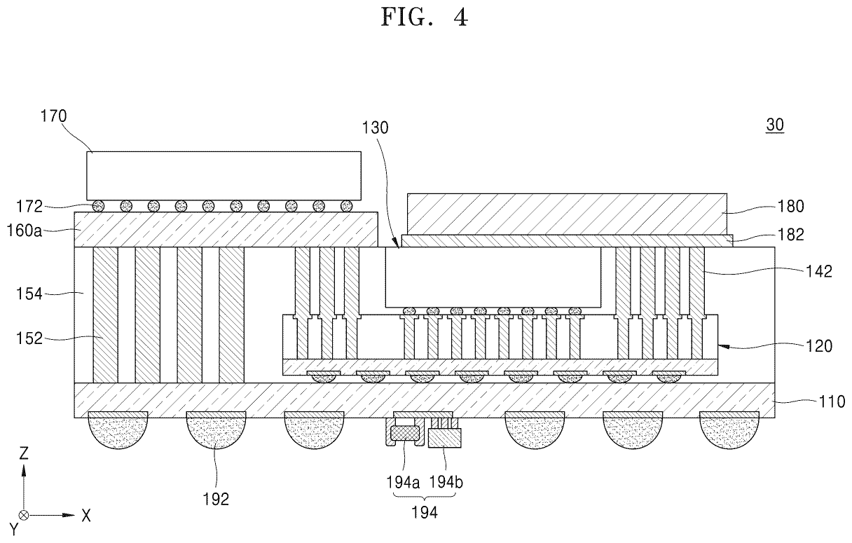

FIG. 4 is a cross-sectional view of a semiconductor package according to one or more embodiments. Descriptions already given above with reference to FIGS. 1 and 2 are briefly given or omitted.

Referring to FIG. 4, a semiconductor package 30 of the present embodiment may be different from the semiconductor package 10 of FIG. 1 in that an upper redistribution substrate 160a only partially overlaps the lower redistribution substrate 110.

In the semiconductor package 30 according to one or more embodiments, the upper redistribution substrate 160a may be disposed to overlap the memory chip 170 in the vertical direction (e.g., Z direction). The upper redistribution substrate 160a may be disposed to be spaced apart from the heat dissipation structure 180 in the first horizontal direction (e.g., X direction). According to one or more embodiments, the upper redistribution substrate 160a may be disposed on some of the plurality of second thermal vias 142 and the plurality of conductive posts 152.

The memory chip 170 may be electrically connected to the upper redistribution substrate 160a. The memory chip 170 may receive a power signal from the outside through the upper redistribution substrate 160a, the conductive post 152, the lower redistribution substrate 110, and the external connection terminal 192. In one or more examples, the memory chip 170 may receive a part of power through a path formed along the plurality of first connection terminals 129, the lower wiring layer 123, the plurality of first thermal vias 125, the plurality of second thermal vias 142, and the upper redistribution substrate 160a.

Although FIG. 4 shows that the upper redistribution substrate 160a does not overlap the second semiconductor chip 130, the embodiments are not limited thereto, and the upper redistribution substrate 160a may be disposed to overlap a portion of the second semiconductor chip 130. In this case, the memory chip 170 may be electrically connected to the second semiconductor chip 130 through the upper redistribution substrate 160a.

In the semiconductor package 30 according to one or more embodiments, as the upper redistribution substrate 160a is disposed to be spaced apart from the heat dissipation structure 180, the heat dissipation structure 180 may be disposed on the second semiconductor chip 130 and some of the second thermal vias 142. The hot spot region of the second semiconductor chip 130 overlaps the heat dissipation structure 180 in the vertical direction (e.g., Z direction), and thus, heat generated by the second semiconductor chip 130 may be transferred to the heat dissipation structure 180. In one or more examples, some of the second thermal vias 142, for example, the remaining second thermal vias 142 that do not overlap the upper redistribution substrate 160a, may be directly connected to the heat dissipation structure 180 through the adhesive layer 182. The first thermal via 125 vertically penetrating through the semiconductor substrate 121 of the first semiconductor chip 120 is directly connected to the second thermal via 142, and the second thermal via 142 is connected to the heat dissipation structure 180, and thus, the heat dissipation effect of the first semiconductor chip 120 may be improved.

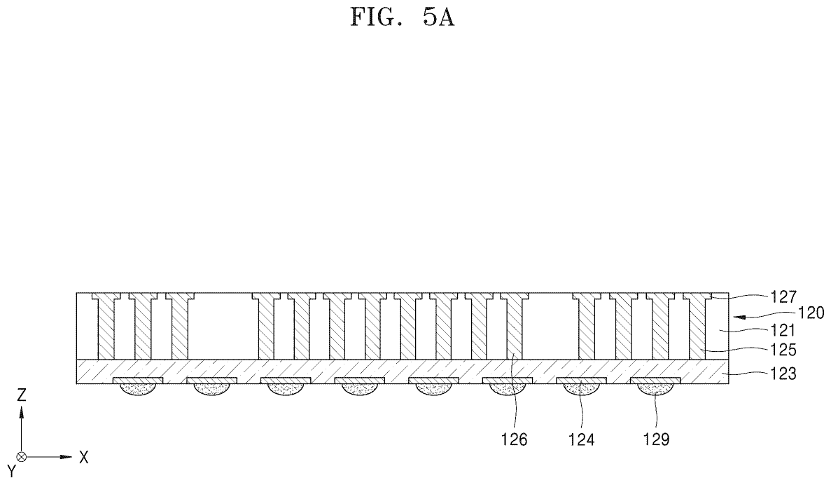

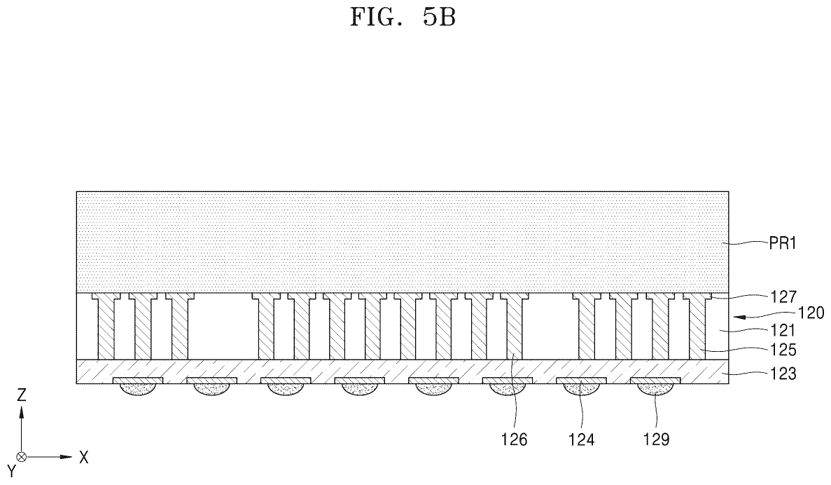

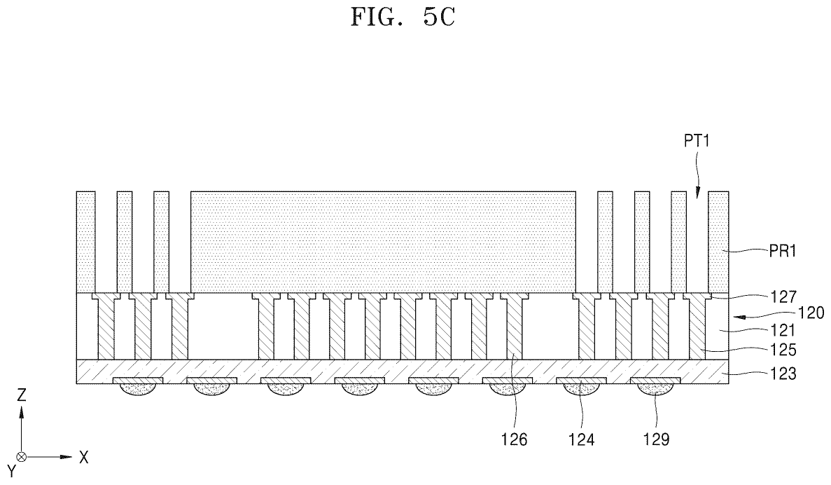

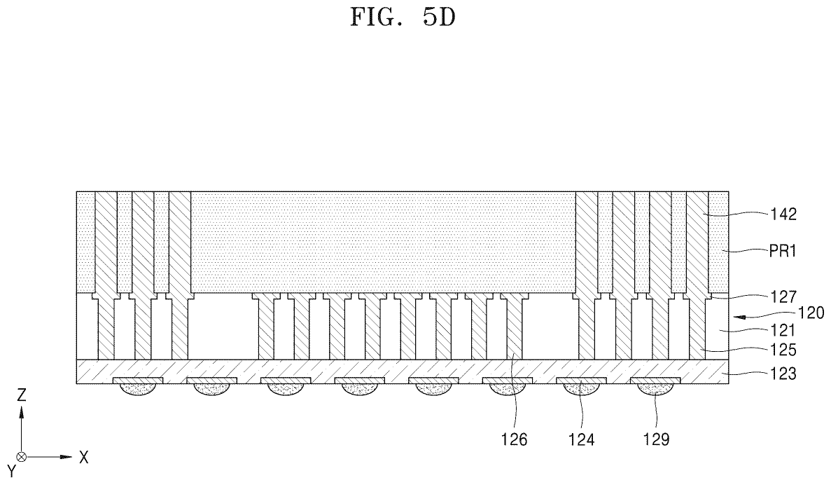

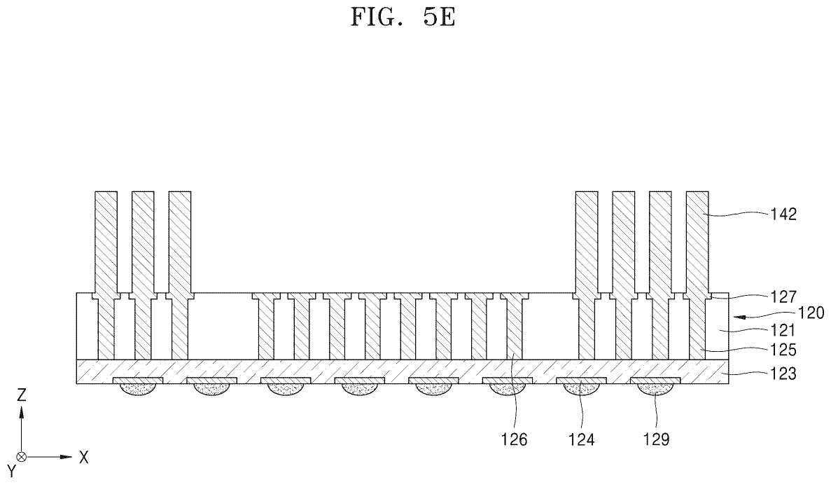

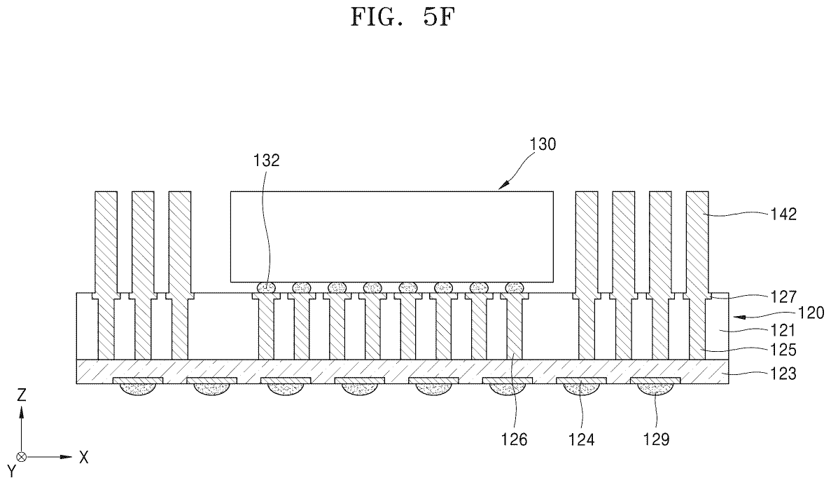

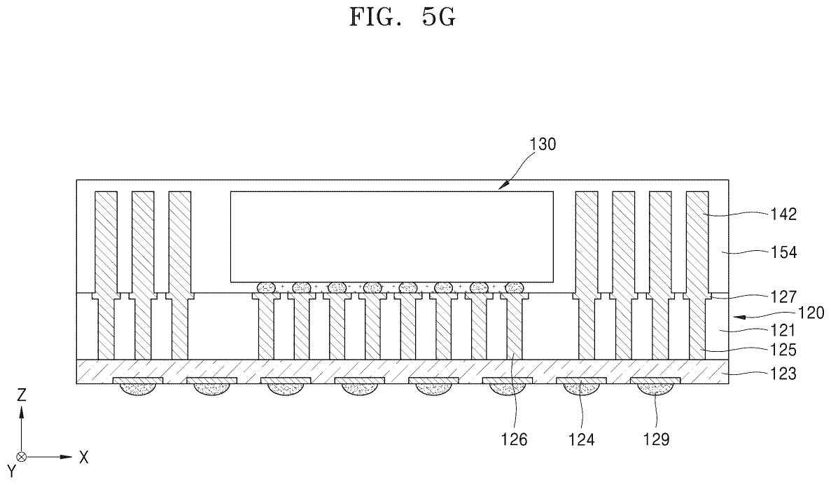

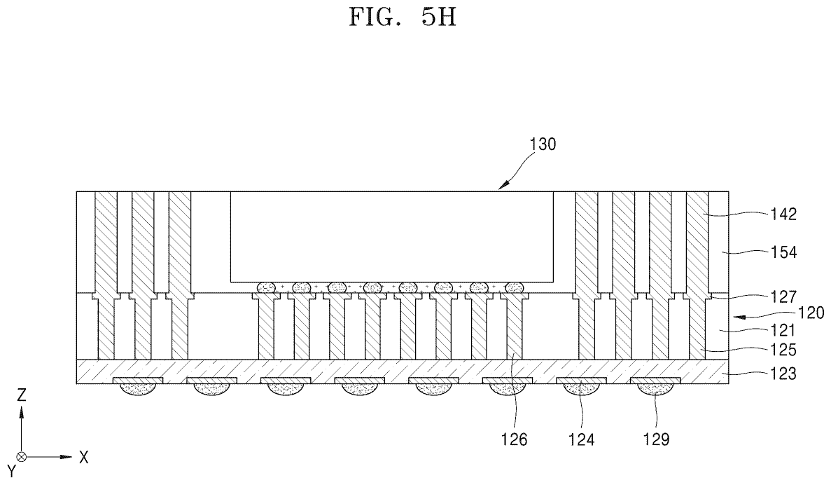

FIGS. 5A to 5H are diagrams schematically showing a process of manufacturing a stacked structure of the first semiconductor chip 120 and the second semiconductor chip 130 of FIG. 2, according to one or more embodiments.

Referring to FIGS. 5A and 5B, in one or more examples, a photoresist RP is applied and baked on the first semiconductor chip 120 to form a photoresist layer PR1.

Referring to FIG. 5C, in one or more examples, the photoresist layer PR1 is exposed and developed to form a plurality of openings PT1 in the outer region of the first semiconductor chip 120. The plurality of openings PT1 may be formed on the first thermal via 125 to overlap the peripheral portion PA of the first semiconductor chip 120. According to embodiment, the plurality of openings PT1 may be formed on the upper connection pad 127.

Referring to FIG. 5D, in one or more examples, the plurality of openings PT1 in FIG. 5C are filled with a conductive material to form the second thermal vias 142 arranged on the first semiconductor chip 120. The second thermal via 142 may be connected to the first thermal via 125. The second thermal via 142 may be formed through electroplating. According to some embodiments, the conductive material may include copper (Cu).

Referring to FIGS. 5E and 5F, in one or more examples, the photoresist layer PR1 (refer to FIG. 5D) is removed, and the second semiconductor chip 130 is mounted on the first semiconductor chip 120. The second semiconductor chip 130 may be disposed to overlap the center portion CA of the first semiconductor chip 120. The second semiconductor chip 130 may be electrically connected to the first semiconductor chip 120 by having the second connection terminals 132 arranged on the through vias 126.

Referring to FIG. 5G, in one or more examples, the molding member 154 is formed to cover the second semiconductor chip 130 and the plurality of second thermal vias 142. The molding member 154 may be formed to cover all of the top surfaces of the second semiconductor chip 130 and the plurality of second thermal vias 142. According to one or more embodiments, in the stacked structure of the first semiconductor chip 120 and the second semiconductor chip 130 constituting the semiconductor package 20 of FIG. 3, the molding member 154 of FIG. 5G may correspond to the first molding member 144.

Referring to FIG. 5H, in one or more examples, a portion of the molding member 154 is removed to expose the top surfaces of the second semiconductor chip 130 and the plurality of second thermal vias 142. According to one or more embodiments, the molding member 154 may be removed through a chemical mechanical polishing (CMP) process.

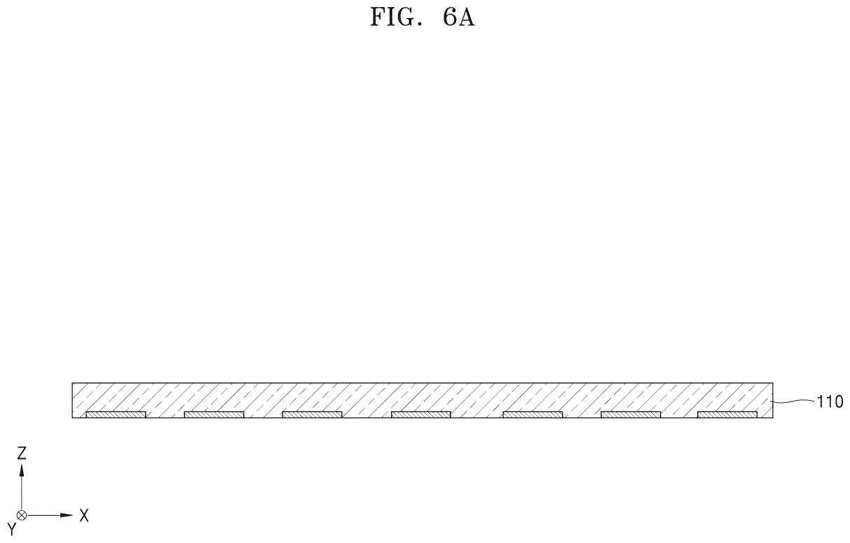

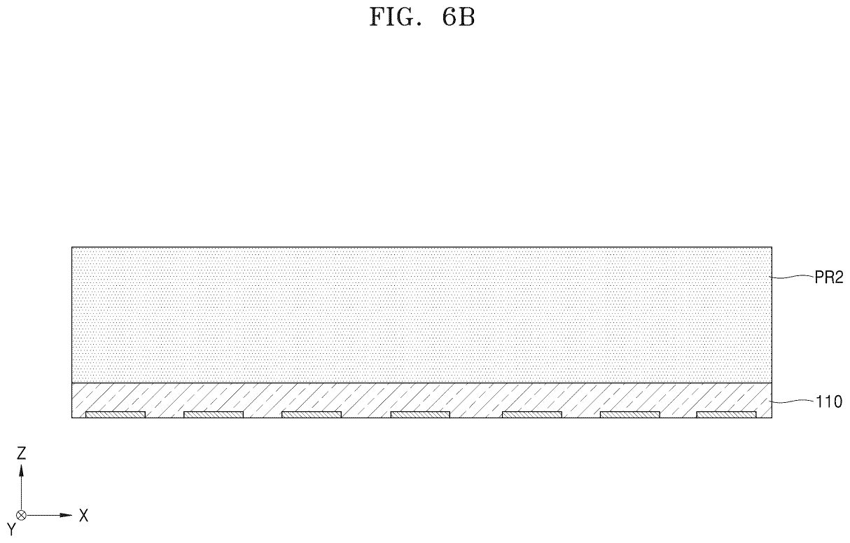

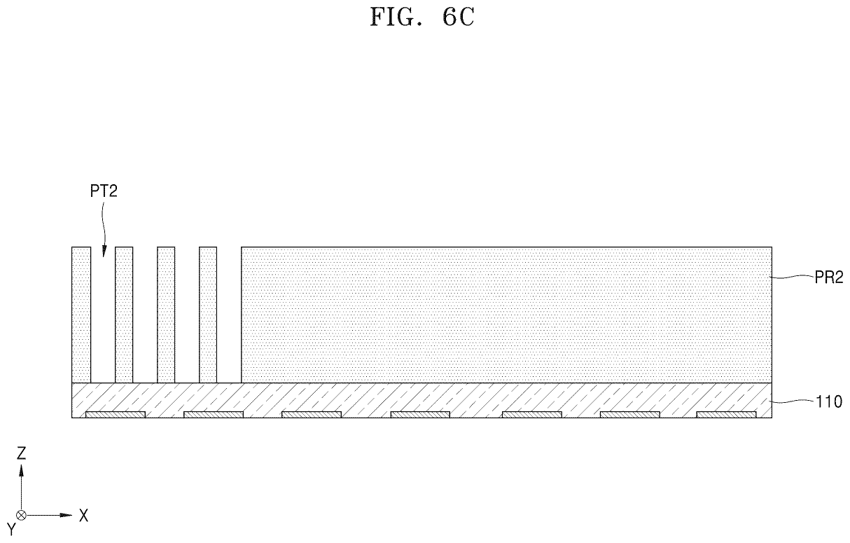

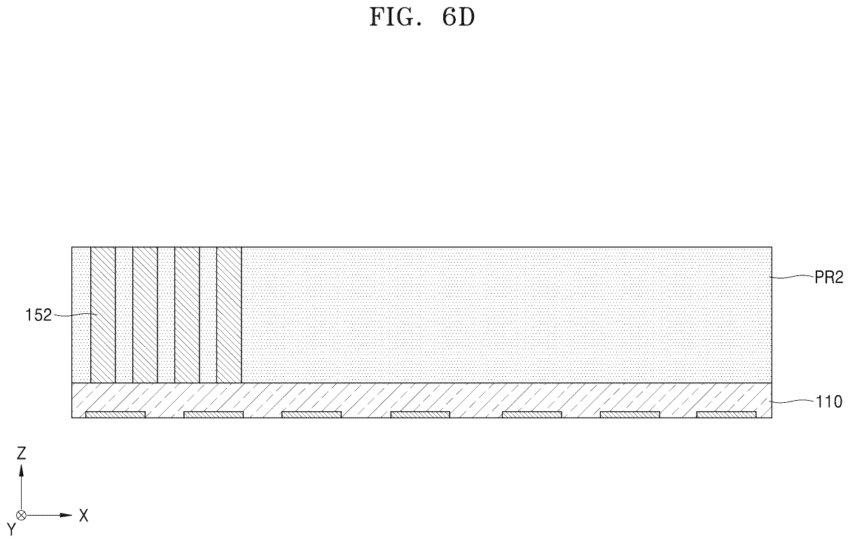

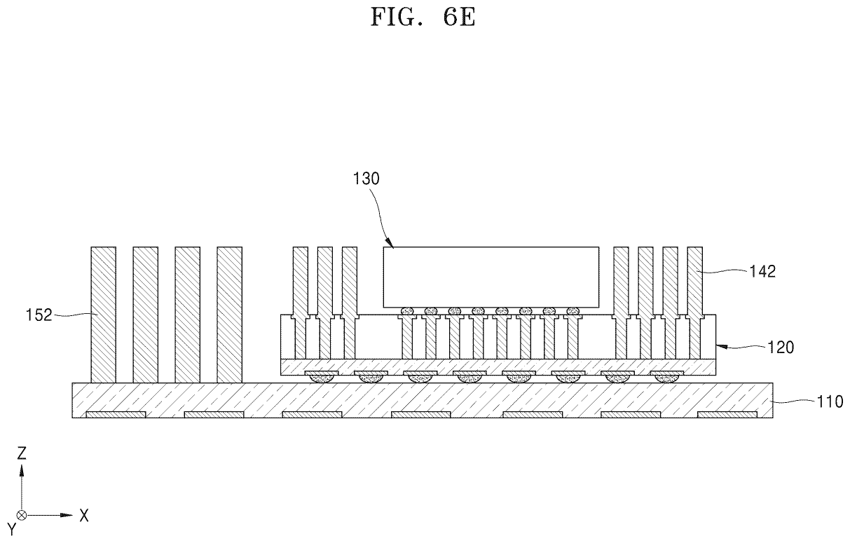

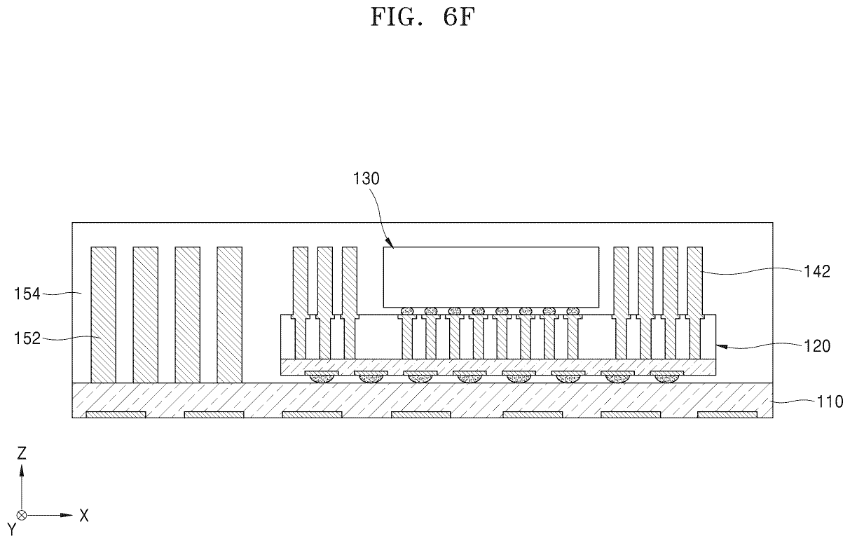

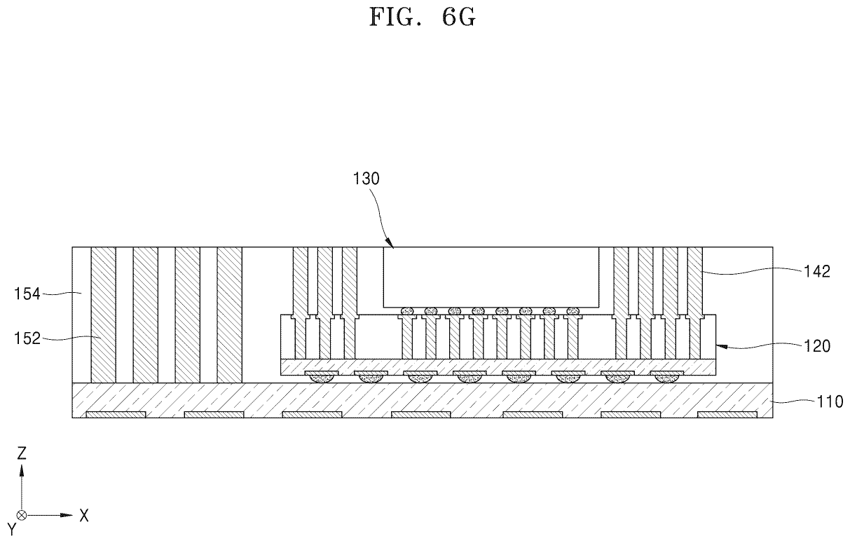

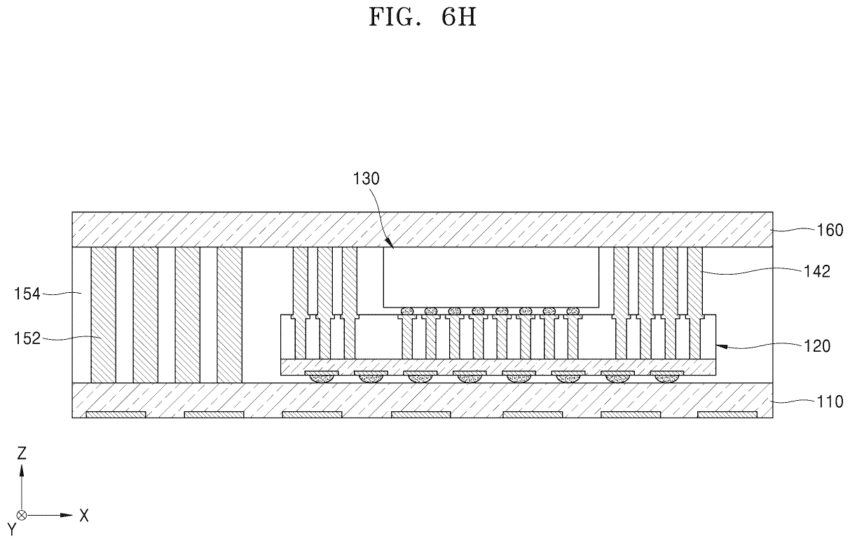

FIGS. 6A to 6H are diagrams schematically showing a process of manufacturing the semiconductor package 10 of FIG. 1, according to one or more embodiments.

Referring to FIGS. 6A and 6B, in one or more examples, the photoresist RP is applied and baked on the lower redistribution substrate 110 to form a photoresist layer PR2.

Referring to FIG. 6C, in one or more examples, the photoresist layer PR2 is exposed and developed to form a plurality of openings PT2 in the lower redistribution substrate 110. The plurality of openings PT2 may be formed in the lower redistribution substrate 110 and deviated leftward in the first horizontal direction (X direction).

Referring to FIG. 6D, in one or more examples, the plurality of openings PT2 of FIG. 6C are filled with a conductive material to form the conductive posts 152 arranged on the lower redistribution substrate 110. The conductive post 152 may be formed through electroplating. The conductive post 152 may include, for example, copper (Cu). The conductive post 152 may be formed through electroplating using a seed metal.

Referring to FIG. 6E, in one or more examples, the photoresist layer PR2 (refer to FIG. 6D) is removed, and the stacked structure of the first semiconductor chip 120 and the second semiconductor chip 130 (hereinafter, referred to as a semiconductor chip stacked structure) is mounted on the lower redistribution substrate 110. To form the semiconductor package 10 of FIG. 1 according to one or more embodiments, the semiconductor chip stacked structure of operation shown in FIG. 5F may be mounted on the lower redistribution substrate 110. In other words, in the operation before formation of a molding member filling the space between the second semiconductor chip 130 and the second thermal via 142 on the first semiconductor chip 120, the semiconductor chip stacked structure is disposed on the lower redistribution substrate 110.

Referring to FIG. 6F, in one or more examples, the molding member 154 covering the semiconductor chip stack structure and the plurality of conductive posts 152 is formed. The molding member 154 may be formed to cover all of the top surfaces of the second semiconductor chip 130, the plurality of second thermal vias 142, and the plurality of conductive posts 152.

Referring to FIG. 6G, in one or more examples, a portion of the molding member 154 is removed to expose the top surfaces of the second semiconductor chip 130, the plurality of second thermal vias 142, and the plurality of conductive posts 152. According to embodiment, the molding member 154 may be removed through a CMP process.

Referring to FIG. 6H, in one or more examples, the upper redistribution substrate 160 is formed on the second semiconductor chip 130, the plurality of second thermal vias 142, and the plurality of conductive posts 152.

Referring to FIG. 6H and FIG. 1 together, the memory chip 170 and the heat dissipation structure 180 are mounted on the upper redistribution substrate 160, and the external connection terminals 192 and the passive devices 194 are attached to the bottom of the lower redistribution substrate 110, and thus, the semiconductor package 10 may be formed.

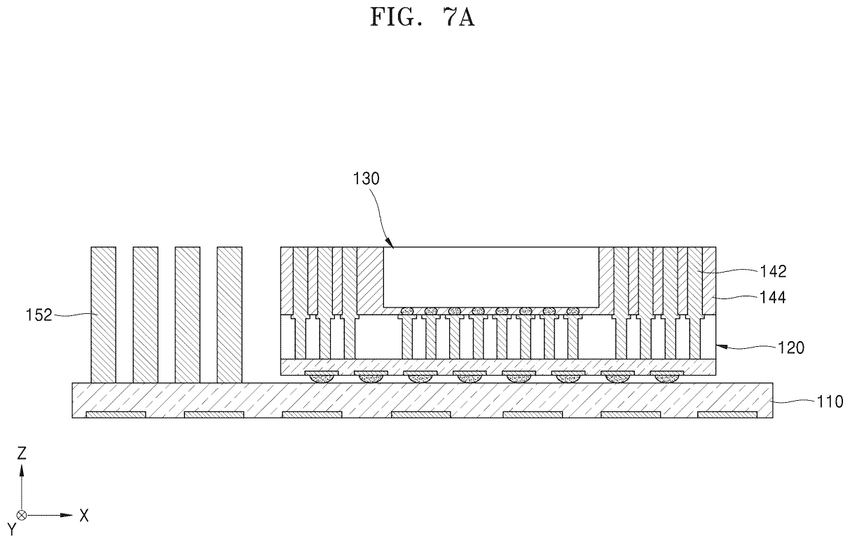

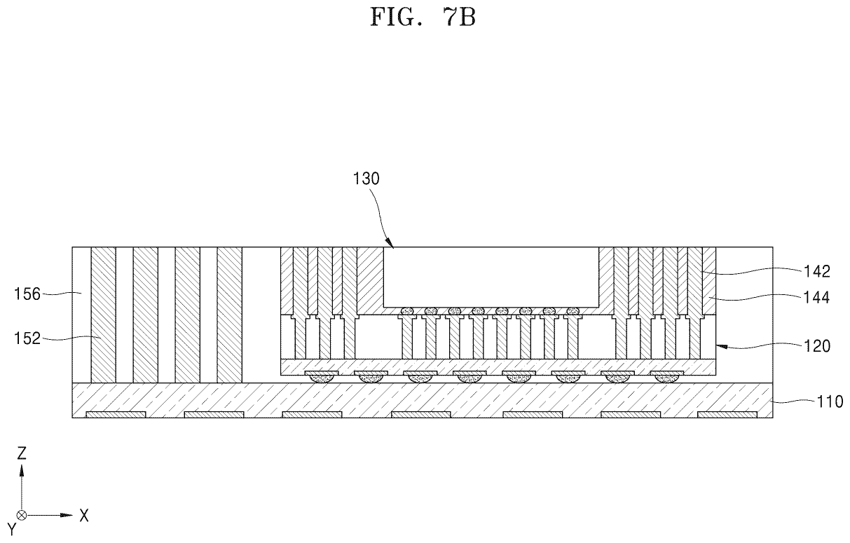

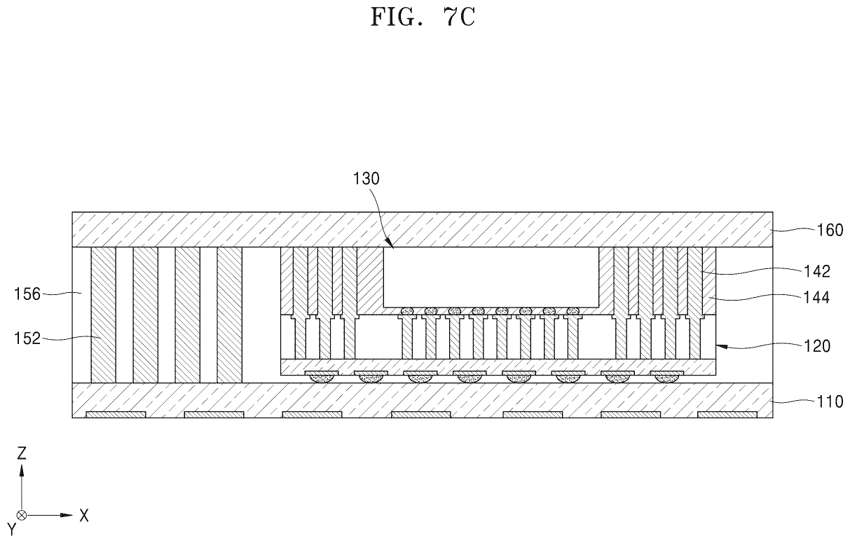

FIGS. 7A to 7C are diagrams schematically showing a process of manufacturing the semiconductor package 20 of FIG. 3. FIGS. 7A to 7C are drawings after the process of FIG. 6D, according to one or more embodiments.

Referring to FIG. 7A, in one or more examples, the photoresist layer PR2 (refer to FIG. 6D) is removed, and the stacked structure of the first semiconductor chip 120 and the second semiconductor chip 130 (hereinafter, referred to as a semiconductor chip stacked structure) is mounted on the lower redistribution substrate 110. To form the semiconductor package 20 of FIG. 3 according to one or more embodiments, the semiconductor chip stacked structure of operation shown in FIG. 5H may be mounted on the lower redistribution substrate 110. In other words, after a molding member filling the space between the second semiconductor chip 130 and the second thermal via 142 is formed on the first semiconductor chip 120, the semiconductor chip stacked structure is disposed on the lower redistribution substrate 110. Here, the molding member 154 in FIG. 5H may be considered as the first molding member 144.

Referring to FIG. 7B, in one or more examples, the second molding member 156 covering the semiconductor chip stack structure and the plurality of conductive posts 152 is formed. After the second molding member 156 is formed to cover all of the top surfaces of the second semiconductor chip 130, the plurality of second thermal vias 142, and the plurality of conductive posts 152, the second molding member 156 may be partially removed to expose the top surfaces of the second semiconductor chip 130, the plurality of second thermal vias 142, and the plurality of conductive posts 152. The second molding member 156 may include the same material as the first molding member 144. However, according to embodiments, the first molding member 144 and the second molding member 156 may include different materials.

Referring to FIG. 7C, in one or more examples, the upper redistribution substrate 160 is formed on the second semiconductor chip 130, the plurality of second thermal vias 142, and the plurality of conductive posts 152.

Referring to FIG. 7C and FIG. 3 together, the memory chip 170 and the heat dissipation structure 180 are mounted on the upper redistribution substrate 160, and the external connection terminals 192 and the passive devices 194 are attached to the bottom of the lower redistribution substrate 110, and thus the semiconductor package 20 may be formed.

While the embodiments have been particularly shown and described with reference to embodiments thereof, it will be understood that various changes in form and details may be made therein without departing from the spirit and scope of the following claims.

What is claimed is:

1. A semiconductor package comprising:
a first redistribution substrate;
a first semiconductor chip on the first redistribution substrate, the first semiconductor chip comprising a semiconductor substrate and a plurality of first thermal vias penetrating through the semiconductor substrate in a first direction;
a second semiconductor chip disposed on a center portion of the first semiconductor chip; and
a plurality of second thermal vias arranged on a peripheral portion of the first semiconductor chip and arranged on an outer portion of the second semiconductor chip,
wherein the plurality of second thermal vias are connected to the plurality of first thermal vias, respectively.

2. The semiconductor package of claim 1, further comprising:
a plurality of conductive posts arranged on the first redistribution substrate and spaced apart from the first semiconductor chip in a second direction perpendicular to the first direction;
a second redistribution substrate disposed on the second semiconductor chip, the plurality of second thermal vias, and the plurality of conductive posts;
a molding member that contacts and surrounds the first semiconductor chip, the second semiconductor chip, the plurality of second thermal vias, and the plurality of conductive posts between the first redistribution substrate and the second redistribution substrate; and
a heat dissipation structure disposed on the second redistribution substrate and overlapping at least a portion of the second semiconductor chip in the first direction.

3. The semiconductor package of claim 2, wherein the heat dissipation structure overlaps one or more of the plurality of second thermal vias in the first direction.

4. The semiconductor package of claim 1, wherein the first semiconductor chip further comprises a plurality of upper connection pads arranged on the plurality of first thermal vias, and
the plurality of second thermal vias are connected to the plurality of upper connection pads by directly contacting the plurality of upper connection pads.

5. The semiconductor package of claim 1, wherein a width of a second thermal via in a second direction perpendicular to the first direction is larger than a width of a first thermal via in the second direction.

6. The semiconductor package of claim 1, wherein the first semiconductor chip comprises:
a plurality of through vias penetrating through the semiconductor substrate in the first direction;
a wiring layer disposed below the semiconductor substrate; and
a plurality of first connection terminals arranged at a bottom of the wiring layer, and
the first semiconductor chip is electrically connected to the first redistribution substrate through the plurality of first connection terminals.

7. The semiconductor package of claim 6, further comprising a plurality of external connection terminals arranged at a bottom of the first redistribution substrate,
wherein the first thermal vias are connected to the plurality of external connection terminals through the wiring layer, the plurality of first connection terminals, and the first redistribution substrate.

8. The semiconductor package of claim 6, wherein the plurality of through vias are arranged through the center portion of the semiconductor substrate, and
the plurality of first thermal vias are arranged through the peripheral portion of the semiconductor substrate.

9. The semiconductor package of claim 6, wherein the second semiconductor chip comprises a plurality of second connection terminals arranged at a bottom of the second semiconductor chip, and
the second semiconductor chip is electrically connected to the plurality of through vias through the plurality of second connection terminals.

10. The semiconductor package of claim 6, wherein the second semiconductor chip exchanges signals with the first semiconductor chip through the plurality of through vias of the first semiconductor chip, and receives power through a path formed along the plurality of first connection terminals of the first semiconductor chip, the wiring layer, and the plurality of through vias.

11. The semiconductor package of claim 2, further comprising a memory chip on the second redistribution substrate and spaced apart from the heat dissipation structure in the second direction.

12. The semiconductor package of claim 11, wherein the memory chip exchanges memory signals with the second semiconductor chip through the second redistribution substrate.

13. The semiconductor package of claim 11, wherein the memory chip receives power through a path formed along the plurality of first thermal vias, the plurality of second thermal vias, and the second redistribution substrate.

14. The semiconductor package of claim 1, further comprising one or more passive devices arranged on a bottom surface of the first redistribution substrate.

15. A semiconductor package comprising:
a first redistribution substrate;
a first semiconductor chip on the first redistribution substrate and comprising a semiconductor substrate and a plurality of first thermal vias penetrating through the semiconductor substrate in a first direction;
a second semiconductor chip disposed on a center portion of the first semiconductor chip;
a plurality of second thermal vias arranged on a peripheral portion of the first semiconductor chip and arranged on an outer portion of the second semiconductor chip;
a plurality of conductive posts arranged on the first redistribution substrate and spaced apart from the first semiconductor chip in a second direction perpendicular to the first direction;
a second redistribution substrate on the second semiconductor chip, the plurality of second thermal vias, and the plurality of conductive posts;
a first molding member that contacts and surrounds the second semiconductor chip and the plurality of second thermal vias on the first semiconductor chip; and
a second molding member that contacts and surrounds the first semiconductor chip, the first molding member, and the plurality of conductive posts, between the first redistribution substrate and the second redistribution substrate,
wherein the plurality of second thermal vias are connected to the plurality of first thermal vias, respectively.

16. The semiconductor package of claim 15, wherein a width of a second thermal via in the second is larger than a width of a first thermal via in the second direction.

17. The semiconductor package of claim 15, further comprising a heat dissipation structure disposed on the second redistribution substrate and overlapping at least a portion of the second semiconductor chip in the first direction.

18. The semiconductor package of claim 17, wherein the heat dissipation structure overlaps one or more of the plurality of second thermal vias in the first direction.

19. The semiconductor package of claim 17, further comprising a memory chip disposed on the second redistribution substrate and spaced apart from the heat dissipation structure in the second direction.

20. A semiconductor package comprising:
a first redistribution substrate;
a first semiconductor chip on the first redistribution substrate and comprising a semiconductor substrate and a plurality of first thermal vias penetrating through the semiconductor substrate in a first direction;
a second semiconductor chip disposed on a center portion of the first semiconductor chip;
a plurality of second thermal vias arranged on a peripheral portion of the first semiconductor chip and arranged on an outer portion of the second semiconductor chip;
a plurality of conductive posts arranged on the first redistribution substrate and spaced apart from the first semiconductor chip in a second direction perpendicular to the first direction;
a second redistribution substrate disposed on one or more of the plurality of second thermal vias and the plurality of conductive posts;
a molding member that contacts and surrounds the first semiconductor chip, the second semiconductor chip, the plurality of second thermal vias, and the plurality of conductive posts on the first redistribution substrate; and
a heat dissipation structure disposed on the second semiconductor chip to overlap at least a portion of the second semiconductor chip and the remaining second thermal vias of the plurality of second thermal vias in the first direction,
wherein the plurality of second thermal vias are connected to the plurality of first thermal vias, respectively.
